(19) United States
(12) Patent Application Publication
(10) Pub. No.: US 2024/0234512 A9
(43) Pub. Date: Jul. 11, 2024

(54) VERTICAL SEMICONDUCTOR COMPONENT ON THE BASIS OF GALLIUM NITRIDE WITH A STRUCTURED INTERMEDIATE LAYER

(71) Applicant: Robert Bosch GmbH, Stuttgart (DE)

(72) Inventors: Kevin Dannecker, Reutlingen (DE); Stefan Regensburger, Renningen (DE)

(21) Appl. No.: 18/488,729

(22) Filed: Oct. 17, 2023

(30) Foreign Application Priority Data
Oct. 19, 2022 (DE) 10 2022 211 042.0

(51) Int. Cl. H01L 29/20; H01L 21/02; H01L 21/304; H01L 21/306; H01L 21/311; H01L 21/3205; H01L 21/768; H01L 29/66

(52) U.S. Cl. CPC H01L 29/2003; H01L 21/0254; H01L 21/304; H01L 21/30604; H01L 21/31116; H01L 21/32051; H01L 21/76873; H01L 29/66666

(57) ABSTRACT

A vertical semiconductor component, in particular transistor, with a semiconductor layer structure for forming a semiconductor component on the basis of gallium nitride (GaN) and at least two, preferably three, electrodes arranged vertically one above the other. The semiconductor layer structure includes a contact semiconductor layer contacted by a vertically lower electrode. An intermediate layer for compensating for the lattice mismatch between a non-comprised foreign substrate and the contact semiconductor layer is arranged vertically below the contact semiconductor layer in some regions.

### FIELD

The present invention relates to a vertical semiconductor component, in particular a transistor, with a semiconductor layer structure for forming a semiconductor component on the basis of gallium nitride. The present invention furthermore relates to a method for producing corresponding semiconductor components.

### BACKGROUND INFORMATION

Vertical semiconductor components are generally described in the related art. In them, the final connection electrodes are arranged on two vertically opposite sides of the semiconductor component, in particular the corresponding semiconductor layer structure for forming a semiconductor component, so that space-saving contacting and a vertical current flow and/or field profile are achieved, which are advantageous for both the performance characteristics and for space consumption.

Although the formation of such vertical semiconductor components on the basis of gallium nitride is particularly desirable since they allow low on-resistances (electrical resistance in the conductive state) with simultaneously higher breakdown field strengths/breakdown voltages than comparable components on the basis of silicon or silicon carbide. Since gallium nitride is relatively expensive as a material, the aim is generally to build or grow the semiconductor layer structure on a foreign substrate without gallium nitride or free of gallium nitride in order to thus minimize the total use of gallium nitride. This approach and use of foreign substrate and the intermediate layers or compensation layers necessary in this context have the disadvantage that direct contacting, in particular contacting on the rear side, preferably for forming a drain electrode, cannot be achieved or at least cannot be achieved without additional processing of the vertically lower or rear layers, in particular of the foreign substrate and/or of the intermediate layer, the exposure of a contact semiconductor layer. However, this causes corresponding effort and can severely affect the stability, in particular the mechanical stability, of the semiconductor component and, for forming the finished semiconductor component, the foreign substrate and/or the intermediate/compensation layers of the layer structure can regularly cause a large to very large height/thickness in the vertical direction (regularly several hundred μm).

### SUMMARY

A vertical semiconductor component according to the present invention with a semiconductor layer structure for forming a semiconductor component on the basis of gallium nitride may have an advantage that sufficient mechanical stability is achieved with simultaneously minimum or at least significantly reduced height of the layer structure. Furthermore, the production effort is lowered and damage to the gallium nitride is avoided.

Against the background of the above explanations, in the vertical semiconductor component according to an example embodiment of the present invention, in particular transistor, with a semiconductor layer structure for forming a semiconductor component on the basis of gallium nitride and at least two, preferably three, electrodes arranged vertically one above the other, wherein the semiconductor layer structure comprises a contact semiconductor layer, which can be contacted with a lower electrode, it is therefore provided that an intermediate layer is arranged/formed vertically below the contact semiconductor layer in some regions between a non-comprised foreign substrate and the contact semiconductor layer.

In other words, this means that the finished semiconductor component no longer comprises any foreign substrate and that the intermediate layer for compensating for the lattice mismatch between the previously used or existing foreign substrate and the contact semiconductor layer is also not completely removed but is structured or reduced to regions or portions of lateral or horizontal surfaces such that, on the one hand, the formation and contacting of an electrode, in particular a drain electrode, is possible with the contact semiconductor layer and, on the other hand, the intermediate layer, which is still present or retained in some regions, achieves or enables mechanical stabilization of the semiconductor component and in particular prevents or at least limits crack formation and the development or extension of cracks.

The semiconductor component according to the present invention may thus provide better stability and better protection against the formation and development of cracks than if the foreign substrate and the intermediate layer are completely removed. The semiconductor component according to the present invention is also significantly thinner in the vertical direction than if selective regions in the foreign substrate and the intermediate layer are removed and the contact semiconductor layer is exposed in these regions in order to form a drain electrode or another electrode, since a majority of the height or vertical thickness of the semiconductor component is caused by the thickness of the foreign substrate.

Advantageous developments of the semiconductor component according to the present invention are disclosed herein.

According to a first, particularly advantageous embodiment of the semiconductor component of the present invention, it can be provided that the intermediate layer is formed or remains in an edge region of the semiconductor component. This can improve the mechanical stability of the final semiconductor component but can also facilitate processing, e.g., cutting or separating, in previous processing or production stages, e.g., prior to separating at wafer levels.

According to an example embodiment of the present invention, it can likewise be advantageously provided that the intermediate layer comprises a plurality of individual layers. For example, it can be provided that the intermediate layer comprises not only a buffer layer but also one or more layers as so-called engineered layers. In such an embodiment of the intermediate layer, it can be provided that all individual layers or at least several individual layers in the fully structured semiconductor component according to the present invention advantageously remain in some regions or are arranged below the contact conductor layer.

Alternatively, according to an example embodiment of the present invention, for example if only a single-ply buffer layer is used, or even in a multi-ply intermediate layer, it can advantageously be provided that only one layer remains in the finished semiconductor component and that, accordingly, not only the foreign substrate but also individual layers, preferably all layers except for a single layer, are removed together with the foreign substrate and only a single-ply intermediate layer, preferably a buffer layer, is structured such that portions of the contact semiconductor layer are exposed and the intermediate layer, preferably in the form of the buffer layer, remains in some regions.

In a further, particularly preferred embodiment of the present invention, it can also be provided that the intermediate layer has a thickness, i.e., an extension in the vertical direction, of 2 to 5 μm, preferably of 3 to 4 μm. In comparison to the much thicker foreign substrate, which is completely removed, this enables a semiconductor layer structure with a low thickness/height in the vertical direction and, as a result of the partially remaining intermediate layer, simultaneously increases the mechanical stability and minimizes or prevents crack formation and crack expansion.

The present invention also comprises a method for producing a vertical semiconductor component, preferably according to one of the example embodiments described above, in particular a transistor, with a semiconductor layer structure for forming a semiconductor component on the basis of gallium nitride and at least two, preferably three, electrodes arranged vertically one above the other, wherein the semiconductor layer structure comprises a contact semiconductor layer contacted by a vertically lower electrode. According to an example embodiment of the present invention, the method comprises the following method steps:
forming a semiconductor layer structure comprising at least one layer on the basis of gallium nitride and a vertically lower contact semiconductor layer, preferably likewise on the basis of gallium nitride, and at least one vertically higher electrode on an intermediate layer arranged on a substrate, in particular a foreign substrate;
arranging, in particular connecting, a carrier material on a side of the semiconductor layer structure facing away from the substrate;
removing the substrate, in particular foreign substrate;
structuring, in particular, lithographically structuring the intermediate layer so that the contact semiconductor layer is exposed in some regions and at least a portion of the intermediate layer remains in some regions;
forming an electrode, at least in the exposed regions of the contact semiconductor layer.

The method according to the present invention, which, in terms of layer growth, layer structuring and any influence and processing of formed, in particular grown, layers, draws on generally conventional methods and techniques of semiconductor technology, can advantageously realize a vertical semiconductor layer structure and a corresponding semiconductor component on the basis of gallium nitride, which, on the one hand, has a minimum thickness or vertical extension and simultaneously provides improved mechanical stability, in particular for preventing and minimizing the formation and expansion of cracks.

In a first, advantageous example embodiment of the method of the present invention, it can be provided that the substrate is first partially removed by a grinding process and is subsequently removed by an etching process, preferably a wet chemical etching process. This achieves a particularly effective and efficient removal of the substrate since a first, vertically lower portion of the substrate can in particular be removed extensively and without risk of damage to the other semiconductor layer structures, in particular at the wafer level prior to separation, by grinding, and only a residual layer of the substrate or of the foreign substrate is removed by a more complex but gentler and more precise etching process. In addition to wet chemical etching, dry chemical etching processes can also be used.

According to a further, advantageous example embodiment of the method of the present invention, it can be provided that a portion of the intermediate layer is preferably removed in an etching process. The so-called engineered layers can, for example, be removed so that only a buffer layer of the intermediate layer remains and is subsequently structured and in particular lithographically structured.

Particularly preferably, according to an example embodiment of the present invention, a portion of the intermediate layer, in particular of the or the engineered layers, can be removed by an etching process, preferably a plasma etching process.

According to an example embodiment of present invention, it can likewise be advantageously provided that the structuring of the intermediate layer or of the still remaining intermediate layer comprises a plasma etching process of an unmarked region. As in the above-described advantageous embodiment for the removal of the engineered layers, plasma etching enables accurate and easily controllable removal suitable for thin layers or layers or layers of small extension in the vertical direction.

In a further, likewise advantageous example embodiment of the present invention, it can be provided that a metal stack layer, preferably comprising aluminum and titanium, is formed under the structured intermediate layer. The metal stack layer can preferably be produced by sputtering, vapor deposition and/or electroplating. In an advantageous embodiment of the method, it can also be provided that forming the metal stack layer comprises an annealing operation.

Furthermore, in a particularly desirable embodiment of the method according to the present invention, it can be provided that a power metallization layer is formed under the metal stack layer, preferably by a sputtering process and/or an electroplating process.

Further advantages, features and details of the present invention result from the following description of preferred embodiments of the present invention and on the basis of the figures.

### BRIEF DESCRIPTION OF THE DRAWINGS

FIGS. 1A-1E show sections through semiconductor layer structures at different processing stages of the method according to the present invention for forming a semiconductor component according to an example embodiment of the present invention.

FIGS. 2A-2C show sections through semiconductor layer structures at different method stages of a method according to an example embodiment of the present invention for forming a semiconductor component according to the present invention.

### DETAILED DESCRIPTION OF EXAMPLE EMBODIMENTS

Identical components or elements with the same function are provided in the figures with the same reference signs.

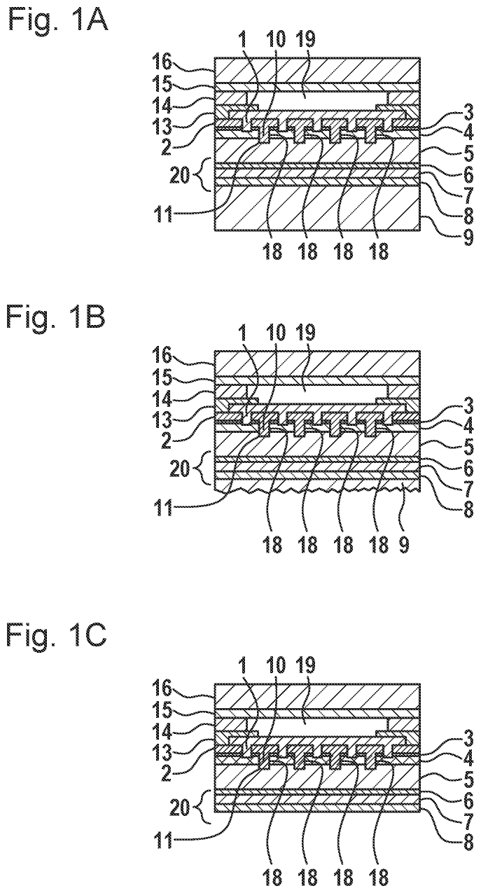

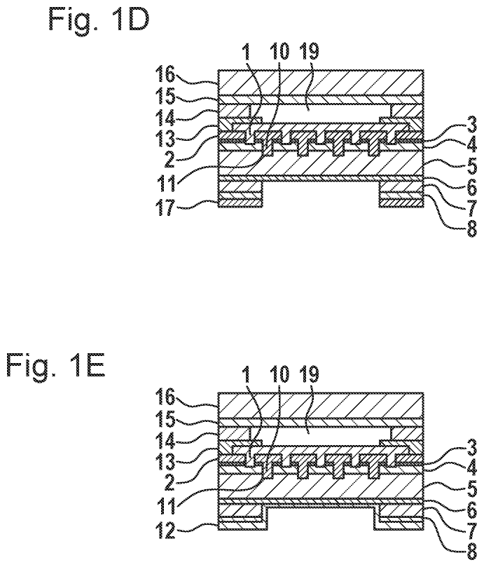

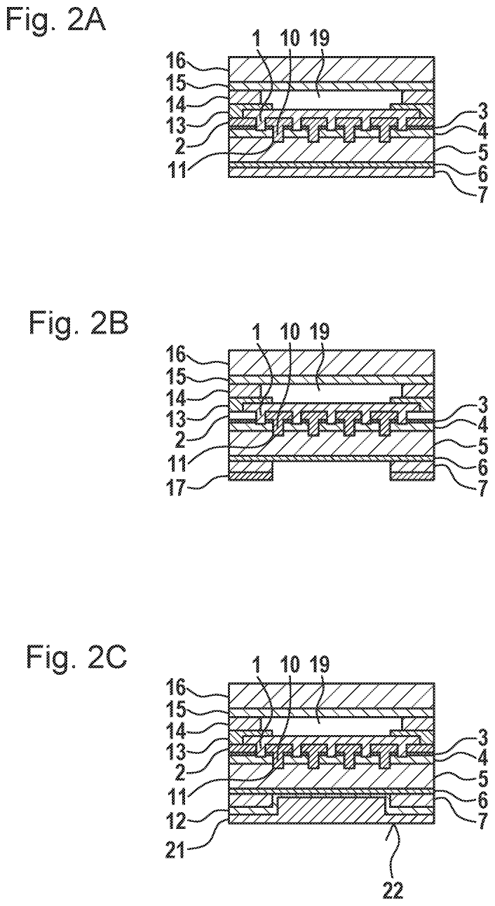

FIG. 1A shows a semiconductor layer structure or a section through such a semiconductor layer structure as is regularly produced in the production of semiconductor components in vertical design using gallium nitride. FIG. 1A, like the following FIGS. 1B to 1E as well as FIGS. 2A to 2C, shows representative cell sections of a trench MOSFET. However, the present invention is not limited to a specific semiconductor component. Instead, the representation of the cell section of the trench MOSFET is merely for visualization.

In the state of FIG. 1A, an engineered layer 8 has first grown on a substrate 9, for example a foreign substrate consisting of poly-aluminum nitride or silicon. In turn, an insulating buffer 7 has grown on the engineered layer 8. A high-doped, preferably n-conductive, contact semiconductor layer 6 is located on the buffer layer 7, followed by a low-doped, preferably n-conductive, drift layer 5, a p-conductive body layer 4, and a high-doped, n-conductive source contact layer 3. The source contact layer 3 as well as the body layer 4 are penetrated by trenches 18 whose side walls and bottom are separated from the gate electrode 10 by a gate dielectric 11. The connection of the gate electrode 10 takes place in a plane perpendicular to the drawing plane and is not shown in the example of FIGS. 1A-1E. The source contact layer 3 and the body layer 4 are contacted by a source electrode 1, which is separated from the gate electrode by an insulating layer 2. Above the source electrode 1 are arranged insulating layers 13 and a moisture barrier 14, which leave open an opening 19 for access to the source electrode 1. Arranged thereon is a bond layer 15 which establishes contact with a vertically top carrier substrate 16.

In order to form the finished semiconductor component, the carrier material 16 can be either removed or contacted through by so-called vias in order to, for example, contact the source electrode 1. However, the present invention relates to contacting the contact semiconductor layer 6 on the rear side or from vertically below.

In a preferred method step of the method according to the present invention, a portion of the substrate 9 is first mechanically removed, in particular by grinding, from vertically below, preferably by rotation of the layer structure by 180° and corresponding processing from above in a method step. In FIG. 1B, it can be seen that the substrate 9 has been removed, in particular ground off, except for a remainder adjacent to the intermediate layer 20 comprising the engineered layers 8 and the buffer layer 7.

Subsequently, the remainder of the foreign substrate can be removed by wet etching or dry etching. The resulting layer structure can be seen in the illustration of FIG. 1C. FIG. 1D shows the combination of subsequent processing steps. In a first step, a mask 17 can be selectively formed, in particular deposited and structured, in some regions of the intermediate layer 20. After the mask 17 has been structured, selective ablation or selective removal of the intermediate layer 20, preferably removal of both the engineered layers 8 and the buffer layer 7, can take place in the regions not covered by the mask 17, so that the contact semiconductor layer 6 is exposed in the regions not covered or concealed by the mask 17. The result of these method steps is shown in the illustration of FIG. 1D.

Subsequently, from the rear side or from vertically below, optionally again by a front-side processing of a layer structure rotated by 180°, a metal stack layer 12 can be formed selectively or over the entire surface, wherein electrical contacting of the semiconductor component and the formation of an electrode, in particular a drain electrode, are achieved in the region of the contact to the contact semiconductor layer 6. The metal stack layer 12 as a full-surface layer or non-selectively applied layer is shown in the illustration of FIG. 1E.

An alternative embodiment of the method according to the present invention for producing a semiconductor component according to the present invention is shown in FIGS. 2A to 2C. FIG. 2A substantially follows the processing state of FIG. 1C. However, in contrast to the method procedure in the example of FIGS. 1A-1E, following the method stage as shown in FIG. 1C, the engineered layer(s) 8 is also completely removed, for example by a plasma etching process, so that only the buffer layer 7 remains above or below the contact semiconductor layer 6. This situation is illustrated in FIG. 2A. Similarly to FIGS. 1A-1E, the mask 17 is subsequently applied onto the buffer layer 7 and structured. After the mask 17 has been structured, the buffer layer 7 is selectively ablated, for example by a further plasma etching process, so that the buffer layer 7 remains only in some regions, namely in the covering region of the mask 17, whereas the contact semiconductor layer 6 is exposed in the unmasked regions. This state is shown in FIG. 2B. After removal of the mask 17, a full-surface formation of a metal stack layer 12 can take place, likewise analogously to FIGS. 1A-1E, in order to form an electrode, in particular a drain electrode, in the transition region to the contact semiconductor layer 6.

The formation of the metal stack layer 12 can preferably comprise an annealing operation. A power metallization layer 21 can preferably be formed, preferably by a sputtering process and/or an electroplating process, below the metal stack layer 12 and planarized in a correspondingly lower surface 22 for further processing of the semiconductor component. The result of this processing, in particular of the formation of the metal stack layer 12 and of the power metallization layer 21, is shown in the illustration of FIG. 1C. A corresponding power metallization layer 21 can also be used in the embodiment of FIGS. 1A-1E.

1-11. (canceled)

12. A vertical semiconductor component, comprising:
a semiconductor layer structure for forming a semiconductor component based on gallium nitride (GaN); and
at least two electrodes arranged vertically one above the other;
wherein the semiconductor layer structure includes:
a contact semiconductor layer contacted by a vertically lower electrode, and
an intermediate layer, configured to compensate for a lattice mismatch between a non-comprised foreign substrate and the contact semiconductor layer, the intermediate layer being arranged vertically below the contact semiconductor layer in some regions.

13. The vertical semiconductor component according to claim 12, wherein the vertical semiconductor component is a transistor.

14. The vertical semiconductor component according to claim 12, wherein the at least two electrodes includes three electrodes.

15. The vertical semiconductor component according to claim 12, wherein the intermediate layer is formed in an edge region of the semiconductor component.

16. The vertical semiconductor component according to claim 12, wherein the intermediate layer includes a plurality of individual layers.

17. The vertical semiconductor component according to claim 12, wherein the intermediate layer has a thickness of 2-5 μm.

18. The vertical semiconductor component according to claim 17, wherein the intermediate layer has a thickness of 3-4 μm.

19. A method for producing a vertical semiconductor component, comprising the following steps:
forming a semiconductor layer structure including at least one layer based on gallium nitride (GaN), a vertically lower contact semiconductor layer, and at least one vertically higher electrode on an intermediate layer arranged on a substrate, the substrate being a foreign substrate;
connecting a carrier material on a side of the semiconductor layer structure facing away from the substrate;
removing the substrate;
lithographically structuring the intermediate layer so that the contact semiconductor layer is exposed in some regions and at least a portion of the intermediate layer remains in some regions; and
forming an electrode at least in the exposed regions of the contact semiconductor layer.

20. The method according to claim 19, wherein the substrate is first removed by a grinding process and subsequently by an etching process.

21. The method according to claim 20, wherein the etching process is a wet chemical etching process.

22. The method according to claim 19, wherein a portion of the intermediate layer is removed in an etching process.

23. The method according to claim 19, wherein the structuring of the intermediate layer includes a plasma etching process of an unmasked region.

24. The method according to claim 19, wherein a metal stack layer, including aluminum and titanium, is formed under the structured intermediate layer.

25. The method according to claim 24 wherein the forming of the metal stack layer includes an annealing operation.

26. The method according to claim 24, wherein a power metallization layer is formed under the metal stack layer.

27. The method according to claim 26, wherein the power metallization layer is formed by a sputtering process and/or an electroplating process.
